(19) United States
(12) Patent Application Publication
(10) Pub. No.: US 2026/0052923 A1
(43) Pub. Date: Feb. 19, 2026

(54) SELECTIVE SIGE ETCHING USING THERMAL F2 WITH ADDITIVE

(71) Applicant: Lam Research Corporation, Fremont, CA (US)

(72) Inventors: Gerome Michel Dominique MELAET, San Leandro, CA (US); Ji ZHU, Castro Valley, CA (US); Mark Naoshi KAWAGUCHI, San Carlos, CA (US); Xuefeng HUA, Foster City, CA (US); Madeleine Parker GORDON, San Jose, CA (US)

(21) Appl. No.: 19/103,350

(22) PCT Filed: Aug. 4, 2023
(86) PCT No.: PCT/US2023/029465

§ 371 Date: Feb. 12, 2025

Related U.S. Application Data
(60) Provisional application No. 63/371,458, filed on Aug. 15, 2022.

(51) Int. Cl. H01L 21/306; C09K 13/00; H01L 21/67

(52) U.S. Cl. CPC H01L 21/30604; C09K 13/00; H01L 21/67069

(57) ABSTRACT

Embodiments herein relate to methods, apparatus, and systems for selectively etching a substrate. The substrate typically includes one or more layers of silicon and one or more layers of silicon germanium. The method may involve receiving the substrate in a process chamber; exposing the substrate to F₂; and exposing the substrate to an additive, where exposing the substrate to F₂ and to the additive results in selectively etching the silicon germanium compared to the silicon, and where the substrate is not exposed to plasma while exposed to F₂. Use of the additive produces a more uniform etch rate for the material being etched than would otherwise be achieved in the absence of the additive.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

As the semiconductor device industry has continued to advance, feature sizes have become increasingly small. Such scaling enables increased density of functional features on a semiconductor substrate. One recent advance is the development of the gate-all-around field effect transistor (GAA FET), in which a gate fully wraps around a conducting channel for enhanced control of current flow through the channel. The channel may be implemented in a number of ways, for example as a nanowire or a nanosheet. The channel is surrounded by a gate oxide, which is then surrounded by the gate. Source and drain regions are positioned on opposite ends of the channel.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Various embodiments herein relate to methods, apparatus, and systems for processing a substrate. The substrate typically includes one or more layers of silicon and one or more layers of silicon germanium. Processing the substrate involves selectively etching the silicon germanium compared to the silicon.

In one aspect of the disclosed embodiments, a method of processing a substrate is provided, the method including: receiving the substrate in a process chamber, the substrate including one or more layers of silicon and one or more layers of silicon germanium; exposing the substrate to F₂; and exposing the substrate to an additive, where exposing the substrate to F₂ and to the additive results in selectively etching the silicon germanium compared to the silicon, and where the substrate is not exposed to plasma while exposed to F₂.

In various embodiments, the additive may include a reducing reactant selected from the group consisting of hydrogen (H₂), hydrogen fluoride (HF), carbon monoxide (CO), sulfur dioxide (SO₂), methane (CH₄). In these or other embodiments, the additive may include an oxidizing reactant selected from the group consisting of oxygen-containing reactants, and elemental halogens other than F₂. In these or other embodiments, the additive may include one or more material selected from the group consisting of a heterocyclic aromatic compound, a heterocyclic aliphatic compound, an alcohol, an amine, an amino acid, an organophosphorus compound, a bifluoride source, an aldehyde, a carbene, an organic acid, and combinations thereof. In these or other embodiments, the additive may adsorb onto the substrate. In these or other embodiments, the additive may include an organic molecule.

In various implementations, the silicon germanium may etch at a more uniform rate than would be achieved without exposing the substrate to the additive.

Various different timing schemes may be used to provide the F₂ and additive. For example, in some embodiments the substrate may be exposed to both F₂ and to the additive at the same time and/or for overlapping durations. In some embodiments, the substrate may be exposed to F₂ at a first time, and the substrate may be exposed to the additive at a second time, the second time being after the first time. In some such embodiments, exposing the substrate to F₂ at the first time may result in etching a first portion of the silicon germanium, and exposing the substrate to the additive at the second time may result in etching a second portion of the silicon germanium, where the silicon germanium is more uniformly etched after etching the second portion compared to after etching the first portion. In some cases, the first portion of the silicon germanium and the second portion of the silicon germanium may have different compositions. In these or other embodiments, the first portion of the silicon germanium and the second portion of the silicon germanium may have different material properties. In some embodiments, the substrate may be exposed to the additive at a first time to modify the silicon germanium, thereby forming a modified silicon germanium, and the substrate may be exposed to F₂ at a second time, the second time being after the first time. In various embodiments, the F₂ and the additive may be delivered to the process chamber in repeated alternating pulses.

In another aspect of the disclosed embodiments, an apparatus for etching a substrate is provided, the apparatus including: one or more process chambers, each process chamber including a substrate support; one or more gas inlets into the process chambers and associated flow-control hardware; and a controller having at least one processor and a memory, where the at least one processor and the memory are communicatively connected with one another, the at least one processor is at least operatively connected with the flow-control hardware, and the memory stores computer-executable instructions for controlling the at least one processor to cause: receiving the substrate in one of the one or more process chambers, the substrate including one or more layers of silicon and one or more layers of silicon germanium, exposing the substrate to F₂, and exposing the substrate to an additive, where exposing the substrate to F₂ and to the additive results in selectively etching the silicon germanium compared to the silicon, and wherein the substrate is not exposed to plasma while exposed to F₂.

In various embodiments, the apparatus may include two or more process chambers, and a load lock for transferring the substrate between the two or more process chambers without exposing the substrate to atmosphere.

A number of different additives can be used. For example, in some embodiments the additive may include a reducing reactant selected from the group consisting of hydrogen (H₂), hydrogen fluoride (HF), carbon monoxide (CO), sulfur dioxide (SO₂), methane (CH₄). In some embodiments the additive may include an oxidizing reactant selected from the group consisting of oxygen-containing reactants, and elemental halogens other than F₂. In these or other embodiments, the additive may include one or more material selected from the group consisting of a heterocyclic aromatic compound, a heterocyclic aliphatic compound, an alcohol, an amine, an amino acid, an organophosphorus compound, a bifluoride source, an aldehyde, a carbene, an organic acid, and combinations thereof. In these or other embodiments, the additive may adsorb onto the substrate. In these or other embodiments, the additive may include an organic molecule.

In various implementations, the silicon germanium may etch at a more uniform rate than would be achieved without exposing the substrate to the additive.

Various timing schemes may be used for delivering the F₂ and the additive. For instance, in some embodiments the substrate may be exposed to both F₂ and to the additive at the same time and/or for overlapping durations. In some embodiments, the substrate may be exposed to F₂ at a first time, and the substrate may be exposed to the additive at a second time, the second time being after the first time. In some such embodiments, exposing the substrate to F₂ at the first time may result in etching a first portion of the silicon germanium, and exposing the substrate to the additive at the second time may result in etching a second portion of the silicon germanium, where the silicon germanium may be more uniformly etched after etching the second portion compared to after etching the first portion. In some cases, the first portion of the silicon germanium and the second portion of the silicon germanium may have different compositions. In these or other embodiments, the first portion of the silicon germanium and the second portion of the silicon germanium may have different material properties. In some embodiments, the substrate may be exposed to the additive at a first time to modify the silicon germanium, thereby forming a modified silicon germanium, and the substrate may be exposed to F₂ at a second time, the second time being after the first time. In various implementations, the F₂ and the additive may be delivered to the process chamber in repeated alternating pulses.

These and other aspects are described further below with reference to the drawings.

### BRIEF DESCRIPTION OF THE DRAWINGS

FIG. 1 is a flowchart for a method of selectively etching a substrate according to various embodiments.

FIGS. 2A and 2B depict a substrate as it undergoes etching according to the method of FIG. 1.

FIG. 3 is a flowchart for a method of selectively etching a substrate according to various embodiments.

FIGS. 4A-4C depict a substrate as it undergoes etching according to the method of FIG. 2.

FIG. 5 is a flowchart for a method of selectively etching a substrate according to various embodiments.

FIGS. 6A-6C depict a substrate as it undergoes etching according to the method of FIG. 5.

FIG. 7A depicts a processing chamber according to various embodiments herein.

FIG. 7B illustrates a vapor delivery system that may be used in the processing chamber of FIG. 7A according to various embodiments.

FIG. 8 shows a multi-station apparatus for performing various processing operations according to certain embodiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Gate-all-around (GAA) technology is rapidly expanding. One material commonly used during the fabrication of a GAA device is silicon germanium (SiGe). For example, the SiGe may be used as a sacrificial material when forming the channels of the GAA device. In various embodiments, Si and SiGe are deposited in alternating layers on a substrate. Recessed features are etched into the alternating layers, and then the SiGe is selectively removed while substantially retaining the Si, which forms the Si channels. The SiGe removal may be done in stages, and additional steps (such as deposition of a spacer or other structure) may occur between these stages. Various embodiments herein relate to selective removal of SiGe (as compared to Si) in the context of forming a GAA device. However, the embodiments are not so limited. The inventions described herein may be applied in other contexts, as well, such as any embodiment where SiGe is selectively etched compared to another material (such as, but not limited to, Si). Such embodiments may be provided in the context of logic or memory applications, for example. In some cases, the SiGe may be only partially removed, and in other cases the SiGe may be substantially entirely removed.

As used herein, etch selectivity refers to the ratio of etch rates between materials. For instance, an etch process that is selective to a first material compared to a second material will provide a higher etch rate with respect to the first material and a lower etch rate with respect to the second material. Such an etch process is understood to preferentially etch the first material compared to the second material.

A number of techniques have been developed for selective removal of SiGe. Broadly, these can be categorized as either plasma-driven processes or thermally-driven processes. Existing plasma-driven SiGe removal processes rely on F radicals generated from fluorine-containing sources such as NF₃, CF₄, SF₆, SiF₄, F₂, or the recombination products of such radicals, primarily F₂. Unfortunately, such plasma-based processes exhibit poor selectivity. Typically, such plasma-based processes remove more Si than desired, which can leave the Si channels thinner than desired, and also places substantial constraints on the geometry of the device. To compensate for the poor selectivity, the plasma-based processes typically operate at relatively high pressure and low temperature, which results in low throughput.

On the other hand, existing thermally-driven SiGe removal processes, which rely on F₂ chemistry, provide substantially better selectivity compared to the plasma-driven processes, with substantial SiGe removal and little to no Si removal. However, such thermally-driven processes suffer from other drawbacks, including a high sensitivity to variations in the SiGe material being etched. This sensitivity results in a non-uniform etch rate between SiGe materials having different compositions or other varying properties. In some cases, the non-uniform etch rate can result in formation of a non-ideal etch front within the SiGe material.

The SiGe material used in semiconductor fabrication can vary widely in its composition and properties. The composition may vary with respect to the concentration of Si and Ge, as well as other elements that may be present in the material. Such elements may be provided intentionally (e.g., as dopants) or unintentionally (e.g., through contamination/diffusion/impurities). Examples of additional elements that may be present in the SiGe may include, but are not limited to, oxygen, carbon, nitrogen, boron, gallium, chlorine, etc. In some embodiments, the SiGe material being removed may have a particular level of non-uniformity with respect to composition. For instance, the SiGe may have a first portion having a first composition, and a second portion having a second composition. The first and second portions of the SiGe may be in different layers of SiGe, or even within the same layer. The first composition and second composition may vary by particular amount. For instance, the first composition and second composition may vary by at least about 0.5%, at least about 1%, at least about 5%, at least about 10%, or at least about 20%, with respect to one or more element therein (including, e.g., Si, Ge, C, O, N, etc.). These percentages are atomic percentages. For instance, in a layer of SiGe having a first portion that is 50% Si and 50% Ge, and a second portion that is 60% Si and 40% Ge, it can be said that both the Si composition and the Ge composition vary by 10% (e.g., |50%-40%|=10%, and |50%-60%|=10%). Similarly, in a layer of SiGe having a first portion that includes 1% oxygen and a second portion that includes 3% oxygen, it can be said that the oxygen concentration varies by 2% (e.g., |1%-3%|=2%).

In these or other embodiments, the SiGe material being removed may have a particular level of non-uniformity with respect to one or more material properties other than (or in addition to) composition. For example, the SiGe may have non-uniform material properties such as conductivity, density, etc. For instance, the SiGe may have a first portion having a first material property, and a second portion having a second material property. As noted above, the first and second portions of the SiGe may be in different layers of SiGe, or even within the same layer. The first and second material properties may vary by a particular amount. For instance, the first material property may be greater than the second material property by at least about 0.5%, at least about 1%, at least about 5%, at least about 10%, at least about 20%, at least about 40%, at least about 60%, at least about 100%, or at least about 200%. For example, in a layer of SiGe having a first portion that has a density of about 4.5 g/cm³ and a second portion that has a density of about 3.8 g/cm³, it can be said that the first portion has a density greater than that of the second portion by about 18% (e.g., (4.5 g/cm³-3.8 g/cm³)/(3.8 g/cm³)*100=18%).

To address these non-uniformity concerns, various embodiments herein utilize a thermally-driven etch process that uses an additive in combination with F₂ to selectively remove SiGe over a second material such as Si. Such additives have not been used previously in combination with F₂ to selectively thermally etch SiGe. Various types of additives may be used, including but not limited to oxidizing reactants and reducing reactants, as described further below.

While the description herein focuses on embodiments in which SiGe is selectively removed compared to Si (or vice versa), it is understood that a different material may be used in place of Si. As such, any description herein related to silicon may also apply to a different material (including but not limited to SiN and SiO) that is present on the substrate and exposed to the etch conditions.

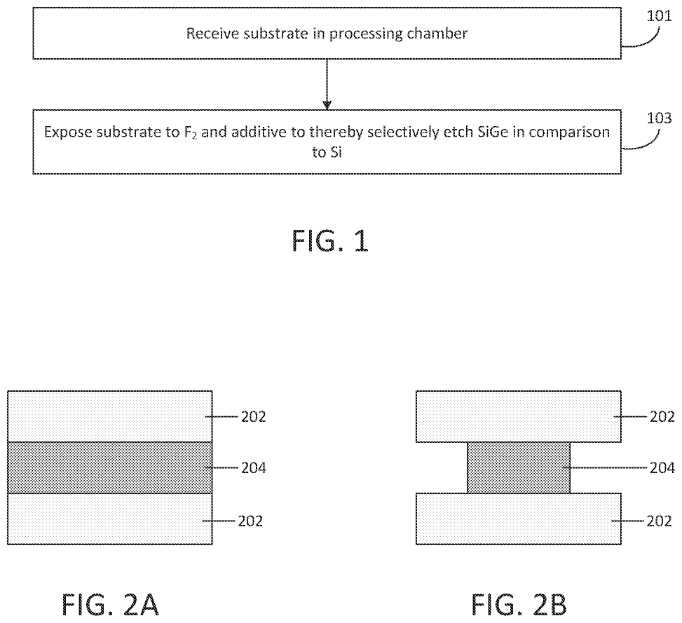

FIG. 1 is a flow chart describing a method of selectively etching SiGe over Si according to various embodiments herein. The method of FIG. 1 is described in the context of FIGS. 2A and 2B, which illustrate a substrate being etched. The method of FIG. 1 begins with operation 101, where a substrate having a stack of alternating layers of Si 202 and SiGe 204 is provided in a process chamber. The SiGe may include non-uniformities with respect to composition and/or one or more other material properties described herein. Recessed features are present on either side of the stack, cutting through the various layers of Si 202 and SiGe 204, as shown in FIG. 2A

At operation 103, the substrate is exposed to chemistry including F₂ and one or more additive to thereby selectively laterally etch the SiGe compared to the Si. Exposing the substrate to the combined flow of F₂ and additive results in a much more uniform etch rate for the SiGe material than would otherwise be achieved in the absence of the additive. FIG. 2B shows the substrate after operation 103. The SiGe is laterally recessed compared to the Si as a result of the selective etching.

In the embodiment of FIG. 1, the F₂ and additive are flowed into the process chamber simultaneously. In a related embodiment, the F₂ and additive may be alternately pulsed into the process chamber. In fact, any of the embodiments and/or steps described herein where the F₂ and additive are flowed together may be modified such that the F₂ and additive are alternately pulsed into the process chamber.

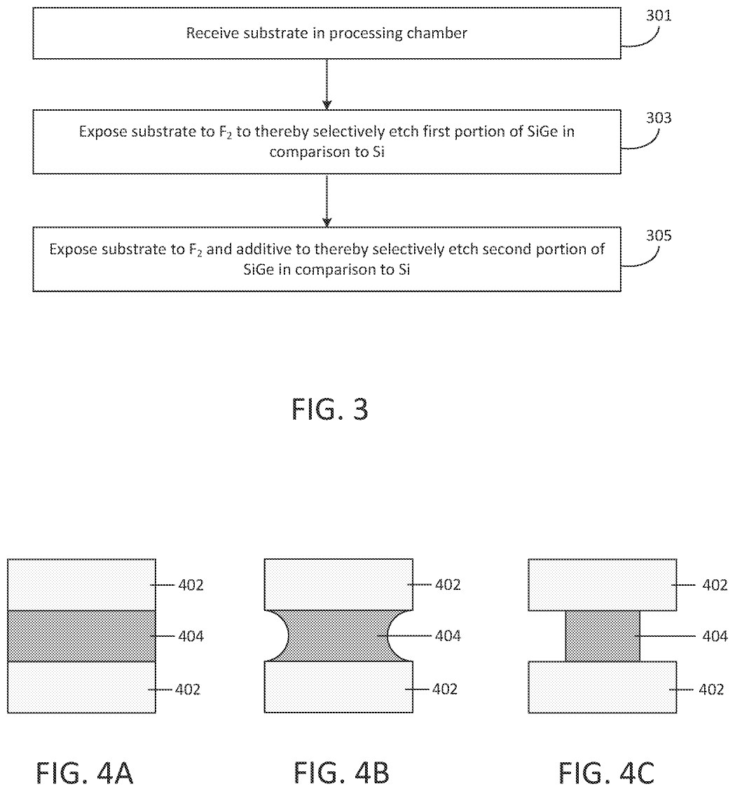

FIG. 3 is a flow chart describing a method of selectively etching SiGe over Si according to various embodiments herein. As compared to the method of FIG. 1, the method of FIG. 3 is different in that it uses a multi-stage approach. This multi-stage approach may enable faster etching and a related higher throughput compared to the single stage approach described in FIG. 1. The method of FIG. 3 is described in the context of FIGS. 4A-4C, which show a substrate being etched. The method of FIG. 3 begins at operation 301, where a substrate having a stack of alternating layers of Si 402 and SiGe 404 is provided in a process chamber. The SiGe may include non-uniformities with respect to composition and/or one or more other material properties described herein. Recessed features are present on either side of the stack, cutting through the various layers of Si 402 and SiGe 404, as shown in FIG. 4A.

At operation 303, the substrate is exposed to F₂ to thereby selectively etch a first portion of the SiGe 404 in comparison to the Si 402, as shown in FIG. 4B. The first portion of the SiGe 404 is also selectively etched in comparison to a second portion of the SiGe 404. In the embodiment shown in FIGS. 4A-4C, the first portion of the SiGe 404 corresponds to the middle portion of the SiGe 404, centered about mid-way between the layers of Si 402. This portion is effectively etched by F₂ (without additive) due to the relatively high concentration of Ge near the middle of the layer of SiGe 404. The second portion of the SiGe 404 is located at the edges (e.g., top and bottom) of SiGe 404, where the SiGe 404 is in contact with the Si 402. As compared to the first portion of the SiGe 404, the second portion of the SiGe 404 has a higher concentration of Si and a lower concentration of Ge. This difference in Si and Ge concentrations (as well as various other differences in material properties described herein) may arise from various sources including, but not limited to, the upstream deposition technique and conditions used to deposit the Si 402 and/or SiGe 404, any upstream techniques and conditions used to etch or treat these layers (which may cause, e.g., ion damage, differences in passivation, etc.), diffusion between the Si 402 and SiGe 404, diffusion between (i) the Si 402 and/or SiGe 404 and (ii) other materials on the substrate, and/or queue time. As shown in FIG. 4B, the etching in operation 303 forms dimples in the SiGe 404, with more extensive etching near the middle of SiGe 404 and less extensive etching near the top and bottom of SiGe 404. The portions of SiGe 404 that are etched less extensively are sometimes referred to as a foot or footing.

Generally, the footing forms in the F₂ thermal etching process (without additive) because this process is highly selective to removing SiGe and Ge over Si. One consequence of this high selectivity is that relatively Si-rich SiGe is not adequately removed (e.g., because it is too compositionally similar to the Si, which is not targeted for removal in this step). The relatively high-Si SiGe that is not adequately removed in operation 303 forms the footing shown in FIG. 4B.

Next, at operation 305, the substrate is exposed to a combination of F₂ and an additive to thereby selectively etch the second portion of SiGe 404 in comparison to the Si 402. Operation 305 also selectively etches the second portion of SiGe 404 in comparison to the first portion of SiGe 404, such that the first portion of SiGe 404 does not become laterally over-etched and a uniform/substantially vertical etch front is created, as shown in FIG. 4C.

In effect, the additive allows for tuning of the selectivity of the etch process so that the remaining SiGe material after operation 303 can be targeted for removal. Generally, inclusion of the additive lowers the selectivity with respect to targeting removal of SiGe (and Ge) over Si. In other words, the additive allows for tuning the etch process in operation 305 by lowering selectivity to target/enable removal of a particular remaining SiGe composition, which may be higher Si compared to the SiGe removed in operation 303 using only F₂. With the lower selectivity resulting from use of the additive, the remaining Si-rich SiGe material can be effectively removed. This is a substantial improvement over the use of F₂ alone.

As mentioned above, the method of FIG. 3 can lead to high quality etch results with high throughput. The multi-stage approach can result in higher throughput compared to the single stage approach of FIG. 1 because various additives described herein can result in a lower etch rate than would otherwise be achieved in the absence of the additive. In other words, the additive can slow the etching process. As such, it is beneficial to etch the first portion of the SiGe quickly using only F₂, and then etch the remaining second portion of the SiGe more slowly using a combination of F₂ and additive. Advantageously, this leads to fast removal of a substantial portion of the SiGe, while providing slower, targeted removal of remaining SiGe, as needed. The result is high quality etching performed at a high throughput.

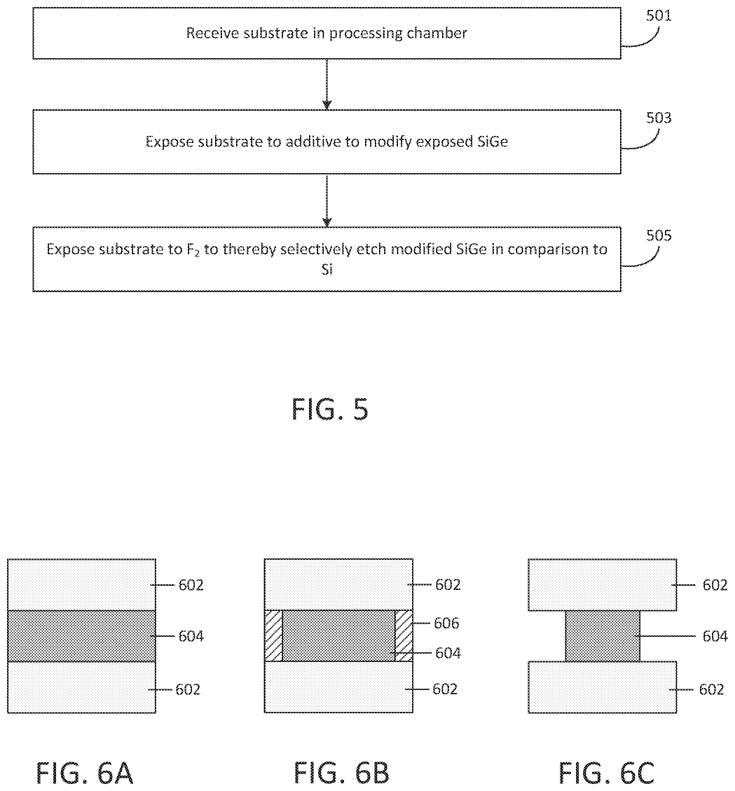

FIG. 5 is a flow chart describing a method of selectively etching SiGe over Si according to various embodiments herein. The method of FIG. 5 is similar to the method of FIG. 3, except that the substrate is exposed to the additive prior to being exposed to F₂. The method of FIG. 5 is described in the context of FIGS. 6A-6C, which show a substrate having Si 602 and SiGe 604 being etched. The method of FIG. 5 begins with operation 501. Operation 501 is analogous to operations 101 and 301, and for the sake of brevity the description will not be repeated.

The method continues with operation 503, where the substrate is exposed to an additive as described herein. The additive modifies the exposed surface of at least the SiGe 604, forming modified SiGe 606, as shown in FIG. 6B. The additive may also modify the Si 602 (such modification is not shown). In one example, modified SiGe 606 may be an oxidized form of SiGe.

In another example, modified SiGe 606 may be a reduced form of SiGe. Various examples are possible. Modifying the surface of SiGe 604 to modified SiGe 606 may counteract and/or overcome non-uniformities in SiGe 604, thereby providing a more uniform SiGe material to etch in the following step.

Next, at operation 505, the substrate is exposed to F₂ to etch the modified SiGe 606 (and in some cases, a portion of SiGe 604 that has not been modified). The substrate may be optionally exposed to one or more additive during operation 505. In various other cases, no additive is provided during operation 505, and the gas provided to the process chamber during this step is just F₂ (or F₂ with an inert gas). It may be desirable to omit the additive during operation 505 to maximize the etch rate.

The methods described in relation to FIGS. 3 and 5 both involve multi-stage techniques, where a different set of reactants is provided for each stage. While FIGS. 3 and 5 show only a single iteration of each stage, it should be understood that these operations may be repeated in a periodic manner. For instance, with respect to the method of FIG. 3, operations 303 and 305 may be repeated any number of times. Similarly, with respect to the method of FIG. 5, operations 503 and 505 may be repeated any number of times.

Although FIGS. 2A, 4A, and 6A show the substrate starting with a Si/SiGe stack having vertical sidewalls (e.g., such that neither the Si nor the SiGe is laterally recessed), and FIGS. 2B, 4C, and 6C show the substrate ending with laterally recessed SiGe, this is not always the case. Any of the methods described herein can be performed on a different structure, for example one in which the SiGe has already been partially laterally etched. In such cases, the SiGe material may be partially removed (similar to what is shown in FIGS. 2B, 4C, and 6C), or the SiGe material may be completely or substantially completely removed. In some cases, one or more of the methods described herein may be performed at a first time to remove a portion of the SiGe material from a substrate as shown in FIGS. 2A, 2B, 4A-4C, and 6A-6C, and then one or more of the methods described herein may be performed at a second time to remove all remaining portions of the SiGe material. Other processing steps may occur after the first time and before the second time. Such processing steps may include, but are not limited to, deposition of a spacer material, thinning silicon wires, and any other steps that may be taken in the context of forming a gate-all-around device or another semiconductor device that utilizes both Si and SiGe.

### Additives

In the embodiments herein, a substrate is etched using a combination of F₂ and an additive. As used herein, an additive is a material (other than F₂ or an inert gas) that is provided to the process chamber for etching a material on the substrate. In some embodiments, the additive may be chemically reactive with one or more material on the substrate and/or with one or more other reactants provided to the process chamber. In some embodiments, the additive (or a material generated at least in part from the additive) may act as a catalyst. In some embodiments, the additive (or a material generated at least in part from the additive) may adsorb onto the substrate (e.g., through chemisorption and/or physisorption, without reacting), which may have the effect of blocking access to such sites for other reactants such as the F₂. A combination of such mechanisms may also be used. The additive may be co-flowed with the F₂, as described in the method of FIG. 1, or it may be flowed separately from the F₂ (e.g., before and/or after the substrate is exposed to F₂), as described in the methods of FIGS. 3 and 5.

The additive may be selected from a number of different types of additives. For instance, in some cases the additive may be a heterocycle compound, a heterocyclic aromatic compound, a halogen-substituted heterocyclic aromatic compound, a heterocyclic aliphatic compound, an alcohol, an amine, a fluoroamine, an amino acid, an organophosphorus compound, an oxidizing reactant, a reducing reactant, a bifluoride source, ammonia, an aldehyde, a carbene, or an organic acid. In some cases, more than one additive may be used. In some embodiments, the additive may be a boron-containing Lewis acid or Lewis adduct. Boron trifluoride (BF₃) is an example of a Lewis acid that forms the acid-base adduct BF₄₋. In some cases, the additive may fall into two or more of the categories listed above.

### Heterocyclic Aromatic Compounds:

In certain embodiments, the additive is a heterocyclic aromatic compound. The term “aromatic” is defined above. A heterocyclic aromatic compound is an aromatic compound that includes a 5-, 6- or 7-membered ring, unless otherwise specified, containing one, two, three, or four non-carbon heteroatoms (e.g., independently selected from the group consisting of nitrogen, oxygen, phosphorous, sulfur, or halo). Example heterocyclic aromatic compounds that may be used include, but are not limited to, picoline, pyridine, pyrrole, imidazole, thiophene, N-methylimidazole, N-methylpyrrolidone, benzimidazole, 2,2-bipyridine, dipicolonic acid, 2,6-lutidine, 4-N,N-dimethylaminopyridine, and azulene. In some cases, a heterocyclic aromatic compound may be methylated. In some cases, a heterocyclic aromatic compound may follow the Hückel 4n+2 rule. In some cases, the additive is a halogen-substituted aromatic compound. A halogen-substituted aromatic compound is an aromatic compound that includes at least one halogen bonded to the aromatic ring. As used herein, halogen or halo refers to F, Cl, Br, or I. Example halogen-substituted aromatic compounds include, but are not limited to, 4-bromopyridine, chlorobenzene, 4-chlorotoluene, fluorobenzene, etc.

### Heterocyclic Aliphatic Compounds:

In some embodiments, the additive is a heterocyclic aliphatic compound. As used herein, “aliphatic” means a hydrocarbon group having at least one carbon atom to 50 carbon atoms (C₁₋₅₀), such as one to 25 carbon atoms (C₁₋₂₅), or one to ten carbon atoms (C₁₋₁₀), and which includes alkanes (or alkyl), alkenes (or alkenyl), alkynes (or alkynyl), including cyclic versions thereof, and further including straight- and branched-chain arrangements, and all stereo and position isomers as well. A heterocyclic aliphatic compound is an aliphatic compound that includes a 5-, 6- or 7-membered ring, unless otherwise specified, containing one, two, three, or four non-carbon heteroatoms (e.g., independently selected from the group consisting of nitrogen, oxygen, phosphorous, sulfur, or halo). Example heterocyclic aliphatic compounds include pyrrolidine, piperidine, etc.

### Alcohols:

In some embodiments, the additive is an alcohol having a formula of CₙH₍₂ₙ₊₁₎OH, where n is the number of carbon atoms in the molecule. Example alcohols include, but are not limited to, methanol, ethanol, propanol, butanol, pentanol, etc. In a particular example, the additive is isopropyl alcohol.

### Amines:

In some embodiments, the additive is an amine having a formula of NR¹R²R³, where:
each of R¹, R², and R³ is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof;
in which R¹ and R², taken together with the atom to which each are attached, can optionally form a cycloheteroaliphatic; and
in which R¹, R², and R³, taken together with the atom to which each are attached, can optionally form a cycloheteroaliphatic.

In some embodiments, each of R¹, R², and R³ is independently selected from alkyl, alkenyl, alkynyl, heteroalkyl, heteroalkenyl, heteroalkynyl, haloalkyl, haloalkenyl, haloalkynyl, haloheteroalkyl, haloheteroalkenyl, haloheteroalkynyl, aryl, heterocyclyl, heteroaryl, alkyl-aryl, alkenyl-aryl, alkynyl-aryl, alkyl-heterocyclyl, alkenyl-heterocyclyl, alkynyl-heterocyclyl, alkyl-heteroaryl, alkenyl-heteroaryl, alkynyl-heteroaryl, heteroalkyl-aryl, heteroalkenyl-aryl, heteroalkynyl-aryl, heteroalkyl-heterocyclyl, heteroalkenyl-heterocyclyl, heteroalkynyl-heterocyclyl, heteroalkyl-heteroaryl, heteroalkenyl-heteroaryl, heteroalkynyl-heteroaryl, or any combinations thereof. In particular disclosed embodiments, the amine may further be substituted with one or more substituents, such as alkoxy, amide, amine, hydroxyl, thioether, thiol, acyloxy, silyl, cycloaliphatic, aryl, aldehyde, ketone, ester, carboxylic acid, acyl, acyl halide, cyano, halogen, sulfonate, nitro, nitroso, quatemary amine, pyridinyl (or pyridinyl wherein the nitrogen atom is functionalized with an aliphatic or aryl group), alkyl halide, or any combinations thereof.

In some embodiments, when at least one of R¹, R², and R³ is aliphatic, haloaliphatic, haloheteroaliphatic, or heteroaliphatic, the additive is an alkyl amine. The alkyl amine can include dialkylamines, trialkyl amines, and derivatives thereof. Example alkyl amines include dimethylisopropylamine, N-ethyldiisopropylamine, trimethylamine, dimethylamine, methylamine, triethylamine, t-butyl amine, and the like.

In other embodiments, when at least one of R¹, R², and R³ includes a hydroxyl, the additive is an alcohol amine. In one instance, at least one of R¹, R², and R³ is an aliphatic group substituted with one or more hydroxyls. Example alcohol amines include 2-(dimethylamino)ethanol, 2-(diethylamino)ethanol, 2-(dipropylamino)ethanol, 2-(dibutylamino)ethanol, N-ethyldiethanolamine, N-tertbutyldiethanolamine, and the like.

In some embodiments, when R¹ and R², taken together with the atom to which each are attached, form a cycloheteroaliphatic, the additive can be a cyclic amine. Example cyclic amines include piperidine, N-alkyl piperidine (e.g., N-methyl piperidine, N-propyl piperidine, etc.), pyrrolidine, N-alkyl pyrrolidine (e.g., N-methyl pyrrolidine, N-propyl pyrrolidine, etc.), morpholine, N-alkyl morpholine (e.g., N-methyl morpholine, N-propyl morpholine, etc.), piperazine, N-alkyl piperazine, N,N-dialkyl piperazine (e.g., 1,4-dimethylpiperazine), and the like.

In other embodiments, when at least one of R¹, R², and R³ includes an aromatic, the additive is an aromatic amine. In some embodiments, at least one of R¹, R², and R³ is aromatic, aliphatic-aromatic, or heteroaliphatic-aromatic. In other embodiments, both R¹ and R² includes an aromatic. In yet other embodiments, R¹ and R² and optionally R³, taken together with the atom to which each are attached, from a cycloheteroaliphatic that is an aromatic. Example aromatic amines include aniline, histamine, pyrrole, pyridine, imidazole, pyrimidine, and the derivatives thereof.

In some embodiments, the additive may include an amine selected from the group consisting of methylamine, dimethylamine, trimethylamine, ethylamine, diethylamine, triethylamine, isopropylamine, 1,2-ethylenediamine, aniline (and aniline derivatives such as N,Ndimethylaniline), N-ethyldiisopropylamine, tert-butylamine, and combinations thereof.

In some embodiments, the additive may include a fluoramine. A fluoramine is an amine having one or more fluorinated substituents. Example fluoroamines that may be used include, but are not limited to, 4-trifluoromethylaniline.

In some embodiments, the additive can be a nitrogenous analogue of a carbonic acid, having a formula R¹N—C(NR²)—NR³. Example additives can include, but are not limited to, guanidine or derivatives thereof.

In some embodiments, the additive may be a relatively low molecular weight amine, e.g., having a molecular weight of less than 200 g/mol or 100 g/mol in certain embodiments. Higher molecular weight amines, including those having long chains and/or heterocyclic compounds with aromatic rings, may be used in some embodiments.

### Amino Acids:

In some embodiments, the additive may include an amino acid. The amino acid may have a formula of R—CH(NR′₂)—COOH, where:
each R and R′ independently are hydroxyl, aliphatic, haloaliphatic, haloheteroaliphatic, heteroaliphatic, aromatic, aliphatic-aromatic, heteroaliphatic-aromatic, or any combination thereof.

Example amino acids that may be used include, but are not limited to, histidine, alanine, and derivatives thereof

### Organophosphorus Compounds:

In some embodiments, the additive may include an organophosphorus compound. The organophosphorus compound may be a phosphate ester, a phosphate amide, a phosphonic acid, a phosphinic acid, a phosphonate, a phosphinate, a phosphine oxide, a phosphine imide, or a phosphonium salt. Example organophosphorus compounds include phosphoric acid and trialkylphosphate. In some cases, the organophosphorous compound is a phosphazene. A phosphazene is an organophosphorus compound that includes phosphorus (V) with a double bond between P and N. The phosphazene may have a formula of RN═P(NR₂)₃ (where each of R and R₂ are independently selected from hydroxyl, aliphatic, haloaliphatic, haloheteroaliphatic, heteroaliphatic, aromatic, aliphatic-aromatic, heteroaliphatic-aromatic, or any combination thereof). In some cases, the phosphazene may have a formula of [X₂PN]ₙ (where X is a halide, alkoxide, or amide). Other types of phosphazenes may be used as desired.

### Oxidizing Reactants:

In some embodiments, the additive includes an oxidizing reactant.

An oxidizing reactant, also referred to as an oxidizing agent, is a substance that tends to bring about oxidation by being reduced and gaining electrons. Example oxidizing reactants include, but are not limited to, oxygen-containing reactants (e.g., oxygen (O₂), nitric oxide (NO), nitrous oxide (N₂O), ozone (O₃), water (H₂O), hydrogen peroxide (H₂O₂), sodium hypochlorite (NaOCl), tetramethyl ammonium hydroxide (N(CH₃)₄⁺OH⁻), etc.), elemental halogens other than F₂ (e.g., chlorine (Cl₂), etc.), and other oxidizing reactants known to those of ordinary skill in the art. The oxidizing reactant can act to oxidize or otherwise passivate exposed surfaces on the substrate, including any exposed SiGe. Without wishing to be bound by theory or mechanism of action, it is believed that such passivation provides a more uniform modified SiGe material for etching, thereby allowing for the F₂ chemistry to etch the modified SiGe at a more uniform rate than would otherwise be achievable in the absence of the oxidizing reactant. Because the F₂ chemistry and the related etch rate are sensitive to differences in the SiGe material, as described above, providing a more uniform SiGe material for etching results in a more uniform etch rate between the different portions of SiGe.

### Reducing Reactants

In some embodiments, the additive includes a reducing reactant. A reducing reactant, also referred to as a reducing agent, is a substance that tends to bring about reduction by being oxidized and losing electrons. Example reducing reactants include, but are not limited to, hydrogen (H₂), hydrogen fluoride (HF), carbon monoxide (CO), sulfur dioxide (SO₂), methane (CH₄), and other reducing reactants known to those of ordinary skill in the art. The reducing reactant may be especially useful in cases where the SiGe includes sub-oxide impurities. The reducing reactant can be used to modify the SiGe material by extracting the oxygen impurities, thereby forming a more uniform modified SiGe material for etching. Because the modified SiGe is more uniform, the resulting etch rate is also more uniform between different portions of the modified SiGe.

### Bifluoride Sources:

In some embodiments, the additive includes a bifluoride source. A bifluoride source is a material that includes or produces bifluoride (HF₂⁻). Example bifluoride sources that may be used include, but are not limited to, ammonium fluoride, aqueous HF, gaseous HF, buffered oxide etch mixture (e.g., a mixture of HF and a buffering agent such as ammonium fluoride), and hydrogen fluoride pyridine. In some embodiments, the bifluoride source (and/or one or more of the other additives listed herein) may react to form HF₂⁻ before or after delivery to the reaction chamber.

### Aldehydes:

In some embodiments, the additive includes an aldehyde having a formula of X—[C(O)]—H, where:

X can be selected from hydrogen, —R¹, —C(R²)₃ or —[C(R³)₂]ₘ—C(O)H, wherein each R¹, R² and R³ independently are selected from hydrogen, aliphatic, haloaliphatic, haloheteroaliphatic, heteroaliphatic, aromatic, aliphatic-aromatic, heteroaliphatic-aromatic, or any combinations thereof, and m is an integer from 0 to 10.

In some embodiments, each of R¹, R², and R³ is, independently, alkyl, alkenyl, alkynyl, heteroalkyl, heteroalkenyl, heteroalkynyl, haloalkyl, haloalkenyl, haloalkynyl, haloheteroalkyl, haloheteroalkenyl, haloheteroalkynyl, aryl, heterocyclyl, heteroaryl, alkyl-aryl, alkenyl-aryl, alkynyl-aryl, alkyl-heterocyclyl, alkenyl-heterocyclyl, alkynyl-heterocyclyl, alkyl-heteroaryl, alkenyl-heteroaryl, alkynyl-heteroaryl, heteroalkyl-aryl, heteroalkenyl-aryl, heteroalkynyl-aryl, heteroalkyl-heterocyclyl, heteroalkenyl-heterocyclyl, heteroalkynyl-heterocyclyl, heteroalkyl-heteroaryl, heteroalkenyl-heteroaryl, heteroalkynyl-heteroaryl, or any combinations thereof. In particular disclosed embodiments, the aldehyde or ketone may further be substituted with one or more substituents, such as aldehyde (—C(O)H), oxo (═O), alkoxy, amide, amine, hydroxyl, thioether, thiol, acyloxy, silyl, cycloaliphatic, aryl, aldehyde, ketone, ester, carboxylic acid, acyl, acyl halide, cyano, halogen, sulfonate, nitro, nitroso, quaternary amine, pyridinyl (or pyridinyl wherein the nitrogen atom is functionalized with an aliphatic or aryl group), alkyl halide, or any combinations thereof.

In some embodiments, when X=aromatic, the additive can be an aromatic aldehyde. Example aromatic aldehydes include benzaldehyde, 1-naphthaldehyde, phthalaldehyde, and the like.

In other embodiments, when X=aliphatic, the additive can be an aliphatic aldehyde. Example aliphatic aldehydes include acetaldehyde, propionaldehyde, butyraldehyde, isovalerylaldehyde, and the like.

In yet other embodiments, when X═—[C(R³)₂]ₘ—C(O)H and m is 0 to 10 or when X=aliphatic or heteroaliphatic substituted with —C(O)H, the additive can be a dialdehyde. Example dialdehydes include glyoxal, phthalaldehyde, glutaraldehyde, malondialdehyde, succinaldehyde, and the like.

In some examples, an aldehyde used as an additive may be selected from the group consisting of acrolein, acetaldehyde, formaldehyde, benzaldehyde, propionaldehyde, butyraldehyde, cinnamaldehyde, vanillin, and tolualdehyde. In these or other cases, an aldehyde used as an additive may be selected from the aldehydes discussed in this section and the aldehydes discussed in the organic solvent section.

### Carbenes:

In some embodiments, the additive includes a carbene. The carbene may have a formula of X—(C:)—Y, where:
each of X and Y can be independently selected from H, halo, —[C(R¹)₂]ₘ—C(R²)₃, —C(O)—R¹, or —C(═NR¹)—R², —NR¹R², —OR², —SR², or —C(R²)₃, wherein each of R¹ and R² is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof, and wherein m is an integer from 0 to 10;
in which R¹ and R², taken together with the atom to which each are attached, can optionally form a cycloheteroaliphatic group; and
in which X and Y, taken together with the atom to which each are attached, can optionally form a cycloaliphatic or cycloheteroaliphatic group.

Furthermore, the additive can be a carbenium cation having a formula R¹—C⁺(R)—R², wherein each of R, R¹, and R² is independently selected from hydrogen, aliphatic, haloaliphatic, haloheteroaliphatic, heteroaliphatic, aromatic, aliphatic-aromatic, heteroaliphatic-aromatic, or any combinations thereof.

In some embodiments, each R, R¹, and R² independently is selected from alkyl, alkenyl, alkynyl, heteroalkyl, heteroalkenyl, heteroalkynyl, haloalkyl, haloalkenyl, haloalkynyl, haloheteroalkyl, haloheteroalkenyl, haloheteroalkynyl, aryl, heterocyclyl, heteroaryl, alkyl-aryl, alkenyl-aryl, alkynyl-aryl, alkyl-heterocyclyl, alkenyl-heterocyclyl, alkynyl-heterocyclyl, alkyl-heteroaryl, alkenyl-heteroaryl, alkynyl-heteroaryl, heteroalkyl-aryl, heteroalkenyl-aryl, heteroalkynyl-aryl, heteroalkyl-heterocyclyl, heteroalkenyl-heterocyclyl, heteroalkynyl-heterocyclyl, heteroalkyl-heteroaryl, heteroalkenyl-heteroaryl, heteroalkynyl-heteroaryl, or any combinations thereof. In particular disclosed embodiments, the carbene may further be substituted with one or more substituents, such as alkoxy, amide, amine, hydroxyl, thioether, thiol, acyloxy, silyl, cycloaliphatic, aryl, aldehyde, ketone, ester, carboxylic acid, acyl, acyl halide, cyano, halogen, sulfonate, nitro, nitroso, quatemary amine, pyridinyl (or pyridinyl wherein the nitrogen atom is functionalized with an aliphatic or aryl group), alkyl halide, or any combinations thereof. In any embodiment of a carbene, each of R¹ and R² can be independently selected.

In some embodiments, when at least one of X or Y is halo, the additive can be a halocarbene. Example, non-limiting halocarbenes include dihalocarbene, such as dichlorocarbene, difluorocarbene, and the like.

In some embodiments, when both X═Y=—NR¹R², the additive can be a diaminocarbene. In one instance, each of R¹ and R² is independently aliphatic. Example diaminocarbenes include bis(diisopropylamino) carbene, and the like.

In other embodiments, when both at least one of X or Y═—NR¹R² and both R¹ and R² within X or within Y are taken together, with the nitrogen atom to which each are attached, to form a cycloheteroaliphatic group, the additive can be a cyclic diaminocarbene. Example cyclic diamino carbenes include bis(N-piperidyl) carbene, bis(N-pyrrolidinyl) carbene, and the like.

In one instance, when both X═Y=—NR¹R² and an R¹ group from X and an R² group from Y are taken together, with the nitrogen atom to which each are attached, to form a cycloheteroaliphatic group, the additive is an N-heterocyclic carbene. Example N-heterocyclic carbenes include imidazol-2-ylidenes (e.g., 1,3-dimesitylimidazol-2-ylidene, 1,3-dimesityl-4,5-dichloroimidazol-2-ylidene, 1,3-bis(2,6-diisopropylphenyl)imidazol-2-ylidene, 1,3-di-tert-butylimidazol-2-ylidene, etc.), imidazolidin-2-ylidenes (e.g., 1,3-bis(2,6-diisopropylphenyl)imidazolidin-2-ylidene), triazol-5-ylidenes (e.g., 1,3,4-triphenyl-4,5-dihydro-1H-1,2,4-triazol-5-ylidene), and the like.

In some embodiments, when X═—NR¹R² and Y═—SR² and an R¹ group from X and an R² group from Y are taken together, with the nitrogen atom to which each are attached, to form a cycloheteroaliphatic group, the additive is acyclic thioalkyl amino carbene. Example cyclic thioalkyl amino carbenes include thiazol-2-ylidenes (e.g., 3-(2,6-diisopropylphenyl)thiazol-2-ylidene and the like).

In some embodiments, when X═—NR¹R² and Y═—C(R²)₃ and an R¹ group from X and an R² group from Y are taken together, with the atom to which each are attached, to form a cycloheteroaliphatic group, the additive is an cyclic alkyl amino carbene. Example cyclic alkyl amino carbenes include pyrrolidine-2-ylidenes (e.g., 1,3,3,5,5-pentamethyl-pyrrolidin-2-ylidene and the like) and piperidin-2-ylidenes (e.g., 1,3,3,6,6-pentamethyl-piperidin-2-ylidene and the like).

Further example carbenes and derivatives thereof include compounds having a thiazol-2-ylidene moiety, a dihydroimidazol-2-ylidene moiety, an imidazol-2-ylidene moiety, a triazol-5-ylidene moiety, or a cyclopropenylidene moiety. Yet other carbenes and carbene analogs include an aminothiocarbene compound, an aminooxycarbene compound, a diaminocarbene compound, a heteroamino carbene compound, a 1,3-dithiolium carbene compound, a mesoionic carbene compound (e.g., an imidazolin-4-ylidene compound, a 1,2,3-triazolylidene compound, a pyrazolinylidene compound, a tetrazol-5-ylidene compound, an isoxazol-4-ylidene compound, a thiazol-5-ylidene compound, etc.), a cyclic alkyl amino carbene compound, a boranylidene compound, a silylene compound, a stannylene compound, a nitrene compound, a phosphinidene compound, a foiled carbene compound, etc. Further example carbenes include dimethyl imidazol-2-ylidene, 1,3-bis(2,4,6-trimethylphenyl)-4,5-dihydroimidazol-2-ylidene, (phosphanyl)(trifluoromethyl)carbene, bis(diisopropylamino) carbene, bis(diisopropylamino) cyclopropenylidene, 1,3-dimesityl-4,5-dichloroimidazol-2-ylidene, 1,3-diadamantylimidazol-2-ylidene, 1,3,4,5-tetramethylimidazol-2-ylidene, 1,3-dimesitylimidazol-2-ylidene, 1,3-dimesitylimidazol-2-ylidene, 1,3,5-triphenyltriazol-5-ylidene, bis(diisopropylamino) cyclopropenylidene, bis(9-anthryl)carbene, norbornen-7-ylidene, dihydroimidazol-2-ylidene, methylidenecarbene, etc.

### Organic Acids:

In some embodiments, the additive includes an organic acid. The organic acid may have a formula of R—CO₂H, wherein R is selected from hydrogen, aliphatic, haloaliphatic, haloheteroaliphatic, heteroaliphatic, aromatic, aliphatic-aromatic, heteroaliphatic-aromatic or any combinations thereof. In certain embodiments, R is alkyl, alkenyl, alkynyl, heteroalkyl, heteroalkenyl, heteroalkynyl, haloalkyl, haloalkenyl, haloalkynyl, haloheteroalkyl, haloheteroalkenyl, haloheteroalkynyl, aryl, heteroaryl, alkyl-aryl, alkenyl-aryl, alkynyl-aryl, alkyl-heteroaryl, alkenyl-heteroaryl, alkynyl-heteroaryl, heteroalkyl-aryl, heteroalkenyl-aryl, heteroalkynyl-aryl, heteroalkyl-heteroaryl, heteroalkenyl-heteroaryl, heteroalkynyl-heteroaryl or any combinations thereof. In particular disclosed embodiments, R may further be substituted with one or more substituents such as, alkoxy, amide, amine, thioether, hydroxyl, thiol, acyloxy, silyl, cycloaliphatic, aryl, aldehyde, ketone, ester, carboxylic acid, acyl, acyl halide, cyano, halogen, sulfonate, nitro, nitroso, quaternary amine, pyridinyl (or pyridinyl wherein the nitrogen atom is functionalized with an aliphatic or aryl group), alkyl halide or any combinations thereof. In certain implementations, the organic acid may be selected from formic acid and acetic acid.

### Substitutions:

Any of the example materials described herein include unsubstituted and/or substituted forms of the compound. Non-limiting example substituents include, e.g., one, two, three, four, or more substituents independently selected from the group consisting of (1) C₁₋₆ alkoxy (e.g., —O—R, in which R is C₁₋₆ alkyl); (2) C₁₋₆ alkylsulfinyl (e.g., —S(O)—R, in which R is C₁₋₆ alkyl); (3) C₁₋₆ alkylsulfonyl (e.g., —SO₂—R, in which R is C₁₋₆ alkyl); (4) amine (e.g., —C(O)NR¹R² or —NHCOR¹, where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, form a heterocyclyl group, as defined herein); (5) aryl; (6) arylalkoxy (e.g., —O—L—R, in which L is alkyl and R is aryl); (7) aryloyl (e.g., —C(O)—R, in which R is aryl); (8) azido (e.g., —N₃); (9) cyano (e.g., —CN); (10) aldehyde (e.g., —C(O)H); (11) C₃₋₈ cycloalkyl; (12) halo; (13) heterocyclyl (e.g., as defined herein, such as a 5-, 6- or 7-membered ring containing one, two, three, or four non-carbon heteroatoms); (14) heterocyclyloxy (e.g., —O—R, in which R is heterocyclyl, as defined herein); (15) heterocyclyloyl (e.g., —C(O)—R, in which R is heterocyclyl, as defined herein); (16) hydroxyl (e.g., —OH); (17)N-protected amino; (18) nitro (e.g., —NO₂); (19) oxo (e.g., ═O); (20) C₁₋₆ thioalkoxy (e.g., —S—R, in which R is C₁₋₆ alkyl); (21) thiol (e.g., —SH); (22) —CO₂R¹, where R¹ is selected from the group consisting of (a) hydrogen, (b) C₁₋₆ alkyl, (c) C₄₋₁₈ aryl, and (d) C₁₋₆ alkyl-C₄₋₁₈ aryl (e.g., —L—R, in which L is C₁₋₆ alkyl and R is C₄₋₁₈ aryl); (23) —C(O)NR¹R², where each of R¹ and R² is, independently, selected from the group consisting of (a) hydrogen, (b) C₁₋₆ alkyl, (c) C₄₋₁₈ aryl, and (d) C₁₋₆ alkyl-C₄₋₁₈ aryl (e.g., —L—R, in which L is C₁₋₆ alkyl and R is C₄₋₁₈ aryl); (24) —SO₂R¹, where R¹ is selected from the group consisting of (a) C₁₋₆ alkyl, (b) C₄₋₁₈ aryl, and (c) C₁₋₆ alkyl-C₄₋₁₈ aryl (e.g., —L—R, in which L is C₁₋₆ alkyl and R is C₄₋₁₈ aryl); (25) —SO₂NR¹R², where each of R¹ and R² is, independently, selected from the group consisting of (a) hydrogen, (b) C₁₋₆ alkyl, (c) C₄₋₁₈ aryl, and (d) C₁₋₆ alkyl-C₄₋₁₈ aryl (e.g., —L—R, in which L is C₁₋₆ alkyl and R is C₄₋₁₈ aryl); and (26) —NR¹R², where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₁₋₆ alkyl-C₄₋₁₈ aryl (e.g., —L—R, in which L is C₁₋₆ alkyl and R is C₄₋₁₈ aryl), (h) C₃₋₈ cycloalkyl, and (i) C₁₋₆ alkyl-C₃₋₈ cycloalkyl (e.g., —L—R, in which L is C₁₋₆ alkyl and R is C₃₋₈ cycloalkyl), wherein in one embodiment no two groups are bound to the nitrogen atom through a carbonyl group or a sulfonyl group.

In certain embodiments, the additive may act as a proton acceptor and promote formation of HF₂⁻. In some such cases, the HF₂⁻ may actively etch one or more materials on the substrate such as an oxide material or another material.

As mentioned above, in some embodiments the additive adsorbs onto the substrate through chemisorption and/or physisorption. Such adsorbing may affect the way in which the F₂ and/or other chemistry interacts with the substrate, thereby allowing the etch selectivity to be carefully tuned. For instance, the additive may adsorb onto the Si and/or Ge, which may have the effect of blocking F₂ or other chemistry from adsorbing onto or reacting with the SiGe, at least to some degree.

In various embodiments herein, an additive is used to reduce the selectivity of an F₂-based thermal etching process. While it is generally desirable for etch selectivity to be high, in some cases it can be too high, particularly when the layer being selectively etched (e.g., SiGe) includes portions that are relatively rich in an element (e.g., Si) that is being selectively retained in another layer. In these cases, the high selectivity prevents the relatively rich portions from being adequately etched. Inclusion of an additive as described herein allows for a controlled reduction in selectivity, which allows for the etch process to be tuned to target removal of desired materials. This is a substantial improvement.

While the description herein typically focuses on use of “an additive,” it is understood that in some embodiments, a combination of different additives may be used. For instance, more than one etching additive may be used (e.g., in some cases two or more oxidizing reactants, two or more reducing reactants, or a combination of both oxidizing and reducing reactants). Similarly, a combination of additives may be selected to provide a particular combination of effects. As an example, an additive which directly reacts with the substrate and/or with another reactant may be combined with an additive that acts as a catalyst and/or with an additive that merely adsorbs onto the substrate. Similarly, an additive that acts as a catalyst may be combined with an additive that merely adsorbs onto the substrate. The additives can be combined as desired for a particular embodiment.

### Processing Conditions

In various embodiments, one or more processing condition may be controlled during etching. Such processing conditions may include substrate support temperature and/or other substrate temperature control features, pressure, reactant flow, timing, etc. Example processing conditions are provided, but are not intended to be limiting unless otherwise stated.

In various embodiments, the temperature of the substrate is controlled during etching, for example by controlling one or more heater and/or cooler configured to heat and/or cool the substrate. Example mechanisms for controlling substrate temperature are further discussed below. In some cases, the temperature of a substrate support may be controlled. The temperature of the substrate and/or substrate support may be controlled between a minimum temperature and a maximum temperature. The minimum temperature may be about −60° C., about −40° C., about −20° C., or about 0° C. In these or other embodiments, the maximum temperature may be about 20° C., about 40° C., about 60° C., about 100° C., or about 130° C.

The pressure within the process chamber may be controlled. For instance, the pressure may be controlled between a minimum pressure and a maximum pressure. The minimum pressure may be about 100 mTorr, about 250 mTorr, or about 1 Torr. In these or other embodiments, the maximum pressure may be about 1 Torr, about 3 Torr or about 10 Torr.

The flow of the various reactants may be controlled. For instance, the flow of any reactant may be controlled between a minimum flow rate and a maximum flow rate. In various embodiments, the minimum flow rate for the F₂ may be about 5 sccm, about 10 sccm, about 50 sccm, or about 100 sccm. In these or other embodiments, the maximum flow rate for the F₂ may be about 50 sccm, about 100 sccm, or about 300 sccm. In these or other embodiments, the minimum flow rate for the additive may be about 5 sccm, about 10 sccm, about 50 sccm, about 100 sccm, or about 200 sccm. In these or other embodiments, the maximum flow rate for the additive may be about 25 sccm, about 100 sccm, about 200 sccm, about 250 sccm, or about 300 sccm. In some cases, inert gas may be provided in addition to the F₂ and additive. The minimum flow rate for the inert gas may be about 10 sccm, or about 40 sccm, or about 100 sccm, or about 1000 sccm. In these or other embodiments, the maximum flow rate for the inert gas may be about 100 sccm, or about 500 sccm, or about 1000 sccm, or about 1500 sccm, or about 2000 sccm.

Another type of processing condition that may be controlled is the ratio between the different species in the process gas. For instance, the ratio of the flowrates of F₂:additive provided to the process chamber may be controlled between a minimum and a maximum. The minimum ratio for the flow rate of F₂:additive into the process chamber may be about 0.5:1, or about 1:1, or about 5:1. The maximum ratio for the flow rate of F₂:additive into the process chamber may be about 5:1, or about 10:1, or about 15:1, or about 20:1, or even higher.

The timing of reactant exposure may also be controlled. As explained above, the additive may be provided together with the F₂, or at a different time. The duration of each reactant exposure can be controlled between a minimum duration and a maximum duration. In various embodiments, the substrate may be exposed to F₂ for a minimum duration of about 500 ms, or about 1 second, or about 5 seconds, or about 60 seconds. In these or other embodiments, the substrate may be exposed to the F₂ for a maximum duration of about 10 seconds, or about 60 seconds, or about 500 seconds, or even longer. In these or other embodiments, the substrate may be exposed to the additive for a minimum duration of about 1 second, or about 5 seconds, or about 60 seconds. In these or other embodiments, the substrate may be exposed to the additive for a maximum duration of about 10 seconds, or about 60 seconds, or about 500 seconds, or even longer.

Another aspect that may be controlled is exposure of the substrate to atmosphere. Specifically, such exposure may be prevented to avoid damaging or otherwise affecting the materials on the substrate surface. It may be particularly beneficial to avoid exposure to atmosphere between (1) the time at which the recessed features are cut into the SiGe/Si stack (this step often precedes the methods described in FIGS. 1, 3, and 5), and (2) the time at which the method of FIG. 1, 3, or 5 is complete (at which point the SiGe may be partially or wholly removed from the substrate). Load locks and/or other appropriate substrate transfer mechanisms may be used to transfer the substrate between different process chambers, as desired for a particular application, without exposure of the substrate to atmosphere.

### Apparatus

The methods described herein may be performed by any suitable apparatus or combination of apparatuses. A suitable apparatus includes hardware for accomplishing the process operations and a system controller having instructions for controlling process operations in accordance with the present invention. For example, in some embodiments, the hardware may include one or more process stations included in a process tool. At least one process station is an etching station.

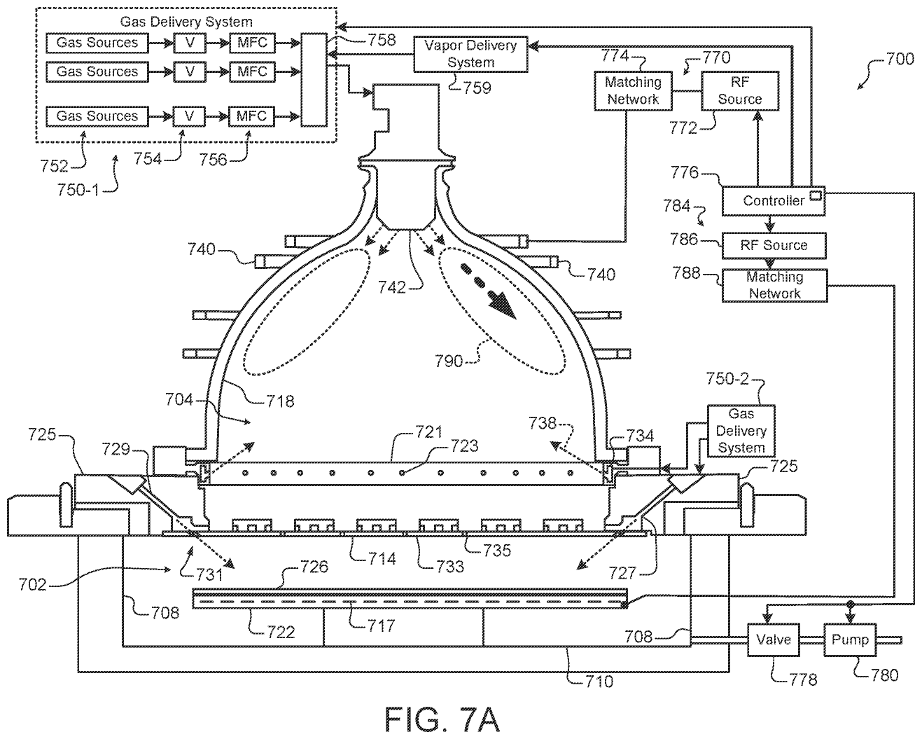

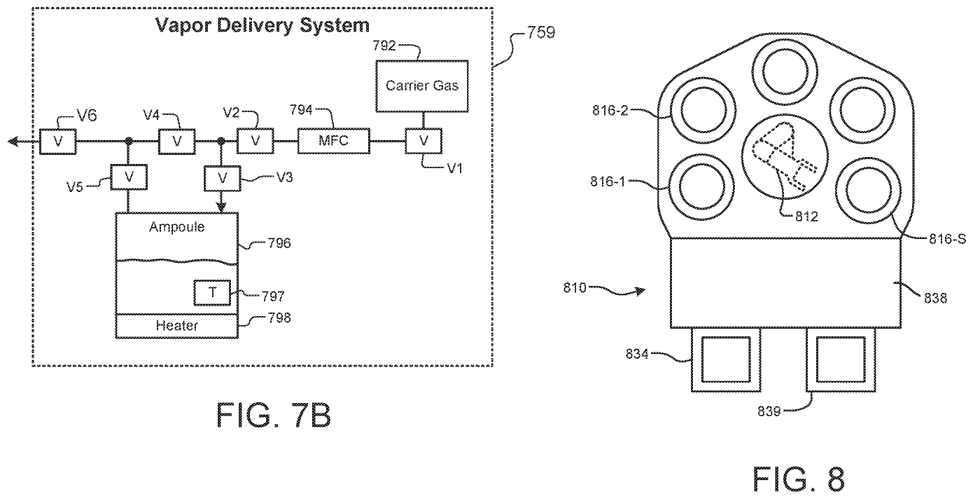

Referring now to FIG. 7A, an example of a substrate processing chamber 700 for performing etching or cleaning at vacuum is shown. While a specific substrate processing chamber is shown and described, the methods may be implemented using other types of substrate processing systems. For example, a substrate processing system operating at atmospheric pressure can be used. In some cases, one or more features described in connection with the substrate processing chamber may be omitted. Such features may include, but are not limited to, hardware for generating plasma. While plasma may be used in some implementations, in other cases the method occurs without any use of plasma. In some cases, plasma may be used for a different processing step, such as for treating a substrate before and/or after etching, or for cleaning a substrate or processing chamber.

In the embodiment of FIG. 7A, the substrate processing chamber 700 includes a lower chamber region 702 and an upper chamber region 704. The lower chamber region 702 is defined by chamber sidewall surfaces 708, a chamber bottom surface 710 and a lower surface of a gas distribution device 714.

The upper chamber region 704 is defined by an upper surface of the gas distribution device 714 and an inner surface of a dome 718. In some examples, the dome 718 rests on a first annular support 721. In some examples, the first annular support 721 includes one or more spaced holes 723 for delivering process gas to the upper chamber region 704. In some examples, the process gas is delivered by the one or more spaced holes 723 in an upward direction at an acute angle relative to a plane including the gas distribution device 714, although other angles/directions may be used. In some examples, a gas flow channel 734 in the first annular support 721 supplies gas to the one or more spaced holes 723.

The first annular support 721 may rest on a second annular support 725 that defines one or more spaced holes 727 for delivering process gas from a gas flow channel 729 to the lower chamber region 702. In some examples, holes 731 in the gas distribution device 714 align with the spaced holes 727. In other examples, the gas distribution device 714 has a smaller diameter and the holes 731 are not needed. In some examples, the process gas is delivered by the one or more spaced holes 727 in a downward direction towards the substrate at an acute angle relative to the plane including the gas distribution device 714, although other angles/directions may be used.

In other examples, the upper chamber region 704 is cylindrical with a flat top surface and one or more flat inductive coils may be used. In still other examples, a single chamber may be used with a spacer located between a showerhead and the substrate support.

A substrate support 722 is arranged in the lower chamber region 702. In some examples, the substrate support 722 includes an electrostatic chuck (ESC), although other types of substrate supports can be used. A substrate 726 is arranged on an upper surface of the substrate support 722 during etching. In some examples, a temperature of the substrate 726 may be controlled by a heater plate 717, an optional cooling plate with fluid channels and one or more sensors (not shown); although any other suitable substrate support temperature control system may be used.

In some examples, the gas distribution device 714 includes a showerhead (for example, a plate 733 having a plurality of spaced holes 735). The plurality of spaced holes 735 extend from the upper surface of the plate 733 to the lower surface of the plate 733. In some examples, the spaced holes 735 have a diameter in a range from 0.1″ to 0.75″. In some examples, the showerhead is made of a conducting material such as aluminum or a non-conductive material such as ceramic with an embedded electrode made of a conducting material.

One or more inductive coils 740 are arranged around an outer portion of the dome 718. When energized, the one or more inductive coils 740 create an electromagnetic field inside of the dome 718. In some examples, an upper coil and a lower coil are used. A gas injector 742 injects one or more gas mixtures from a gas delivery system 750-1.

In some examples, a gas delivery system 750-1 includes one or more gas sources 752, one or more valves 754, one or more mass flow controllers (MFCs) 756, and a mixing manifold 758, although other types of gas delivery systems may be used. In some cases the mixing manifold 758 may be omitted, and the gases may be independently provided to the gas injector 742. An optional vapor delivery system 759 delivers vapor including a carrier gas and another gas to the processing chamber.

A gas splitter (not shown) may be used to vary flow rates of a gas mixture. Another gas delivery system 750-2 may be used to supply an etch gas or an etch gas mixture to the gas flow channels 729 and/or 734 (in addition to or instead of etch gas from the gas injector 742). As used herein, the process gas includes at least F₂ and an additive. The F₂ and additive may be flowed into processing chamber 700 using any combination of gas delivery system 750-1, gas delivery system 750-2, and/or vapor delivery system 759. In various embodiments, the F₂ may be provided separately from the additive, for example with the F₂ flowing into the lower chamber region 702 via holes 731 and spaced holes 727, and the additive flowing into the upper chamber region 704 via gas injector 742 (or vice versa). The F₂ and/or additive may be flowed with a carrier gas such as N₂ or a noble gas. In some embodiments, gas delivery system 750-1, gas delivery system 750-2, and/or vapor delivery system 759 may be configured to provide two or more reactants in a pulsing mode. As a particular example, the F₂ and additive (either or both of which may be flowed with an inert gas) may be alternately pulsed into the substrate processing chamber 700.

Suitable gas delivery systems are shown and described in commonly assigned U.S. patent Ser. No. 14/945,780, entitled “Gas Delivery System” and filed on Nov. 19, 2015, which is hereby incorporated by reference in its entirety. Suitable single or dual gas injectors and other gas injection locations are shown and described in commonly assigned U.S. Pat. No. 10,825,659, entitled “Substrate Processing Chamber Including Multiple Gas Injection Points and Dual Injector” and filed on Jan. 5, 2017, which is hereby incorporated by reference in its entirety.

In some examples, the gas injector 742 includes a center injection location that directs gas in a downward direction and one or more side injection locations that inject gas at an angle with respect to the downward direction. In some examples, the gas delivery system 750-1 delivers a first portion of the gas mixture at a first flow rate to the center injection location and a second portion of the gas mixture at a second flow rate to the side injection location(s) of the gas injector 742. In other examples, different gas mixtures are delivered by the gas injector 742. In some examples, the gas delivery system 750-1 delivers one or more processing gas to the gas flow channels 729 and 734 and/or to other locations in the processing chamber.

An optional plasma generator 770 may be used to generate RF power that is output to the one or more inductive coils 740. Plasma 790 is generated in the upper chamber region 704. In some examples, the plasma generator 770 includes an RF source 772 and a matching network 774. The matching network 774 matches an impedance of the RF source 772 to the impedance of the one or more inductive coils 740. In some examples, the gas distribution device 714 is connected to a reference potential such as ground. A valve 778 and a pump 780 may be used to control pressure inside of the lower and upper chamber regions 702, 704 and to evacuate reactants.

A controller 776 communicates with the gas delivery systems 750-1 and 750-2, the valve 778, the pump 780, and/or the plasma generator 770 to control flow of process gas, purge gas, RF plasma and chamber pressure. In some examples, plasma is sustained inside the dome 718 by the one or more inductive coils 740. One or more gas mixtures are introduced from a top portion of the chamber using the gas injector 742 (and/or spaced holes 723) and plasma is confined within the dome 718 using the gas distribution device 714.

In some examples, an RF bias 784 is provided and includes an RF source 786 and an optional matching network 788. The RF bias power can be used to create plasma between the gas distribution device 714 and the substrate support or to create a self-bias on the substrate 726 to attract ions. The controller 776 may be used to control the RF bias power.

Referring now to FIG. 7B, the optional vapor delivery system 759 can include a bubbler or an ampoule. The vapor delivery system 759 includes a carrier gas source 792 that is connected by a valve V1 to a mass flow controller 794. The vapor delivery system 759 further includes valves V2, V3, V4, V5 and V6 that are configured to prevent flow or to control flow of carrier gas or a mixture of the carrier gas and the solvent. A temperature sensor 797 and a heater 798 are used to control a temperature of the solvent in an ampoule 796. Carrier gas can be supplied by opening valves P1, V2, V4, V5 and V6. Carrier gas and the solvent can be supplied by opening valves V1, V2, V3, V5 and V6 and closing valve V4.

Referring now to FIG. 8, a substrate processing tool 810 according to the present disclosure is shown. The substrate processing tool 810 includes a robot 812 arranged in a central location. The robot 812 may be operated at vacuum or atmospheric pressure. The substrate processing tool 810 includes a plurality of stations 816-1, 816-2, . . . , and 816-S(collectively stations 816) (where S is an integer greater than one) arranged around the robot 812. The stations 816 may be arranged around a center of the substrate processing tool 810 with an equal or irregular angular offset. Examples of stations 816 may include deposition, etch, pre-clean, post clean, spin clean, etc. The substrates may be initially located in a cassette 834. A robot and load lock generally identified at 838 may be used to move the substrates from the cassette 834 to the substrate processing tool 810. When processing is complete, the robot and load lock 838 may return the substrates to the cassette 834 and/or another cassette 839.

In some examples, one of the plurality of stations 816 performs deposition or etching. Another one of the plurality of stations 816 performs cleaning or etching described above. Another one of the plurality of stations such as a spin clean chamber performs the simple wet clean step described above. In some examples, the substrate is moved by the robot 812 from the deposition or etching station, to the cleaning or etching station, and then to the simple wet clean station.

In some examples, two or more etch stations may be provided. One etch station may be configured to etch recessed features into an Si/SiGe stack, for example to form the structures shown in FIGS. 2A, 4A, and 6A, and another etch station may be configured to selectively etch SiGe compared to Si, as described throughout the application. In some cases, either of these stations (or another station) may be configured to perform deposition, such as deposition of a spacer material or other structure in connection with forming a GAA device.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method for processing a substrate, the method comprising:
receiving the substrate in a process chamber, the substrate comprising one or more layers of silicon and one or more layers of silicon germanium;
exposing the substrate to F₂; and
exposing the substrate to an additive,
wherein exposing the substrate to F₂ and to the additive results in selectively etching the silicon germanium compared to the silicon, and wherein the substrate is not exposed to plasma while exposed to F₂.

2. The method of claim 1, wherein the additive comprises a reducing reactant selected from the group consisting of hydrogen (H₂), hydrogen fluoride (HF), carbon monoxide (CO), sulfur dioxide (SO₂), methane (CH₄).

3. The method of claim 1, wherein the additive comprises an oxidizing reactant selected from the group consisting of oxygen-containing reactants, and elemental halogens other than F₂.

4. The method of claim 1, wherein the additive comprises one or more material selected from the group consisting of a heterocyclic aromatic compound, a heterocyclic aliphatic compound, an alcohol, an amine, an amino acid, an organophosphorus compound, a bifluoride source, an aldehyde, a carbene, an organic acid, and combinations thereof.

5. The method of claim 1, wherein the additive adsorbs onto the substrate.

6. The method of claim 1, wherein the additive comprises an organic molecule.

7. The method of claim 1, wherein the silicon germanium etches at a more uniform rate than would be achieved without exposing the substrate to the additive.

8. The method of claim 1, wherein the substrate is exposed to both F₂ and to the additive at the same time and/or for overlapping durations.

9. The method of claim 1, wherein the substrate is exposed to F₂ at a first time, and wherein the substrate is exposed to the additive at a second time, the second time being after the first time.

10. The method of claim 9, wherein exposing the substrate to F₂ at the first time results in etching a first portion of the silicon germanium, wherein exposing the substrate to the additive at the second time results in etching a second portion of the silicon germanium, wherein the silicon germanium is more uniformly etched after etching the second portion compared to after etching the first portion.

11. The method of claim 10, wherein the first portion of the silicon germanium and the second portion of the silicon germanium have different compositions.

12. The method of claim 10, wherein the first portion of the silicon germanium and the second portion of the silicon germanium have different material properties.

13. The method of claim 1, wherein the substrate is exposed to the additive at a first time to modify the silicon germanium, thereby forming a modified silicon germanium, wherein the substrate is exposed to F₂ at a second time, the second time being after the first time.

14. The method of claim 1, wherein the F₂ and the additive are delivered to the process chamber in repeated alternating pulses.

15. An apparatus for etching a substrate, the apparatus comprising:
one or more process chambers, each process chamber comprising a substrate support;
one or more gas inlets into the process chambers and associated flow-control hardware; and
a controller having at least one processor and a memory, wherein
the at least one processor and the memory are communicatively connected with one another,
the at least one processor is at least operatively connected with the flow-control hardware, and
the memory stores computer-executable instructions for controlling the at least one processor to cause:
receiving the substrate in one of the one or more process chambers, the substrate comprising one or more layers of silicon and one or more layers of silicon germanium,
exposing the substrate to F₂, and
exposing the substrate to an additive,
wherein exposing the substrate to F₂ and to the additive results in selectively etching the silicon germanium compared to the silicon, and wherein the substrate is not exposed to plasma while exposed to F₂.

16. The apparatus of claim 15, wherein the apparatus comprises two or more process chambers, and a load lock for transferring the substrate between the two or more process chambers without exposing the substrate to atmosphere.

17. The apparatus of claim 15, wherein the additive comprises a reducing reactant selected from the group consisting of hydrogen (H₂), hydrogen fluoride (HF), carbon monoxide (CO), sulfur dioxide (SO₂), methane (CH₄).

18. The apparatus of claim 15, wherein the additive comprises an oxidizing reactant selected from the group consisting of oxygen-containing reactants, and elemental halogens other than F₂.

19. The apparatus of claim 15, wherein the additive comprises one or more material selected from the group consisting of a heterocyclic aromatic compound, a heterocyclic aliphatic compound, an alcohol, an amine, an amino acid, an organophosphorus compound, a bifluoride source, an aldehyde, a carbene, an organic acid, and combinations thereof.

20. The apparatus of claim 15, wherein the additive adsorbs onto the substrate.

21. The apparatus of claim 15, wherein the additive comprises an organic molecule.

22. The apparatus of claim 15, wherein the silicon germanium etches at a more uniform rate than would be achieved without exposing the substrate to the additive.

23. The apparatus of claim 15, wherein the substrate is exposed to both F₂ and to the additive at the same time and/or for overlapping durations.

24. The apparatus of claim 15, wherein the substrate is exposed to F₂ at a first time, and wherein the substrate is exposed to the additive at a second time, the second time being after the first time.

25. The apparatus of claim 24, wherein exposing the substrate to F₂ at the first time results in etching a first portion of the silicon germanium, wherein exposing the substrate to the additive at the second time results in etching a second portion of the silicon germanium, wherein the silicon germanium is more uniformly etched after etching the second portion compared to after etching the first portion.

26. The apparatus of claim 25, wherein the first portion of the silicon germanium and the second portion of the silicon germanium have different compositions.

27. The apparatus of claim 25, wherein the first portion of the silicon germanium and the second portion of the silicon germanium have different material properties.

28. The apparatus of claim 15, wherein the substrate is exposed to the additive at a first time to modify the silicon germanium, thereby forming a modified silicon germanium, wherein the substrate is exposed to F₂ at a second time, the second time being after the first time.

29. The apparatus of claim 15, wherein the F₂ and the additive are delivered to the process chamber in repeated alternating pulses.
